(19) United States
(12) Patent Application Publication
(10) Pub. No.: US 2015/0031207 A1
(43) Pub. Date: Jan. 29, 2015

(54) Forming multiple gate length transistor gates using sidewall spacers

(71) Applicant: Applied Materials, Inc., Santa Clara, CA (US)

(72) Inventors: Chris Bencher, Cupertino, CA (US); Adam Brand, Palo Alto, CA (US)

(73) Assignee: Applied Materials, Inc., Santa Clara, CA (US)

(21) Appl. No.: 14/121,021

(22) Filed: Jul. 18, 2014

Related U.S. Application Data
(60) Provisional application No. 61/958,489, filed on Jul. 29, 2013.

(51) Int. Cl. H01L 21/308; H01L 21/28

(52) U.S. Cl. CPC H01L 21/3088; H01L 21/3086; H01L 21/3085; H01L 21/28008
USPC 438/696

(57) ABSTRACT

A method of fabricating multiple gate lengths simultaneously on a single chip surface. Hard masking materials which are used as spacers in a field effects transistor generation process are converted into a spacer mask to increase the line density on the chip surface. These hard masking spacers are further patterned by either trimming or by enlarging a portion of a spacer at various locations on a chip surface, to enable formation of multiple gate lengths on a single chip, using a series of process steps which make use of combinations of hydrophobic and hydrophilic materials.

This application claims priority under U.S. Provisional Application Ser. No. 61/958,489, filed Jul. 29, 2013, and entitled: “Technique For Forming Multiple Gate Length Transistor Gates Using Sidewall Spacers”, which is hereby incorporated by reference in its entirety.

### BACKGROUND

1. Field

Field effect transistor fabrication technology which enables the fabrication of multiple gate lengths on a single chip.

2. Description of the Background Art

This section describes background subject matter related to the disclosed embodiments of the present invention. There is no intention, either express or implied, that the background art discussed in this section legally constitutes prior art.

The semiconductor industry has recently used sidewall spacer double patterning up to quadruple the density of patterning during the process of controlling critical gate length. In such instances, the critical gate length has been defined by the width of a sidewall spacer. Designers have been limited to designs based on a single gate width obtained for each sidewall spacer creation step. This is not a desirable result, since the variability in gate lengths available is severely limited. In addition, the size range of the gate lengths is typically limited by imaging and etching techniques which are applied to the entire substrate. In many cases, designers need to do fine tuning of gate lengths of gates across the substrate to optimize devices for timing and power. For example, with a primary gate length of 20 nm, designers may desire to have some gates at 19 nm to speed the timing path, or at 21 nm to lower power consumption.

U.S. Patent Application Publication 2008/0299776 A1 of Bencher et al., entitled: “Frequency Doubling Using Spacer Mask”, published Dec. 4, 2008, describes a method of fabricating a semiconductor stack which makes use of a sacrificial mask and a spacer mask. The sacrificial mask is comprised of a series of lines and the spacer mask has spacer lines adjacent to the sidewalls of the series of lines. The spacer mask is cropped, followed by removal of the sacrificial mask. The cropped spacer mask doubles the frequency of the series of lines which may be transferred to an underlying layer in a subsequent etch process. (Abstract) The content of U.S. Patent Application Publication 2008/0299776 A1 is hereby incorporated by reference into the present application.

In 2008, at electronicsweekly.com/articles/11/03/2008/43310, an article described self-aligned double patterning (SADP), also known as “spacer-based” patterning. This processing technique, which generates pairs of features from a single parent exposure is described as being particularly promising when used in combination with “gridded design rules”. This technology was said to reduce overlay error during processing.

In 2009, an SPIE article available at spie.org/x35993 described the competing technologies for producing semiconductor feature sizes at the 22 nm node “and beyond”. These technologies included double patterning lithography in various forms. Discussed in this article are: 1) A litho-etch-litho-etch (LELE) technique, which was described as costly, with challenging overlay for 22 nm or less; 2) A “Litho-freeze” technique , in which only one etch step is required because a process is used to chemically modify and “freeze” the first-deposited and developed resist prior to depositing and development of a second resist coating, where the process is said to be costly and also is said to have a challenging overlay for 22 nm or less; 3) A self-aligned double patterning process (SADP), where the process is said to require significant extra processing; 4) A dual tone development process (DTD), which is said not to meet 32 nm requirements; and, 5) A double exposure (DE) process which is said to have line edge/line width roughness problems which may limit applicability below 22 nm.

U.S. Pat. No. 7,820,512 B2 to Pillarisetty et al., entitled: “Spacer Patterned Augmentation Of Tri-Gate Transistor Gate Length”, issued Oct. 26, 2010, describes the formation of six transistor static random access memory cells. A method includes forming a semiconductor substrate having N-diffusion and P-diffusion regions. A gate stack is formed over the semiconductor substrate. The gate electrode hard mask is augmented around pass gate transistors with a spacer material. The gate stack is etched using the augmented gate electrode hard mask to form the gate electrodes. The electrodes around the pass gate have a greater length than other gate electrodes. (Abstract).

A publication in Advanced Materials 2012, 24, 26-8-1613, by Dr. Y.-C. Tseng et al., entitled: “Enhanced Lithographic Imaging Layer Meets Semiconductor Manufacturing Specification a Decade Early”, describes the treatment of poly(methyl methacrylate) (PMMA) with aluminum oxide sequential infiltration synthesis (SIS) to define high-resolution (sub 20 nm) patterns . Additional information related to selective growth of Al₂O₃ within a film of polystyrene-block-poly(methyl methacrylate) (PS-b-PMMA) is described in The Journal of Physical Chemistry, Volume 115, Number 36 published on Sep. 15, 2011. The PMMA phase of self-assembled PS-b-PMMA block copolymer thin films is said to be selectively infiltrated with alumina, yielding a inorganic nanostructure mimicking the original block copolymer template, that serves directly as a robust etch mask.

U.S. Pat. No. 8,357,618 B2 to Bencher et al., entitled: “Frequency Doubling Using A Photo-Resist Template Mask”, which issued Jan. 22, 2013, describes a method of doubling the frequency of a lithographic process using a photo-resist template mask. (Abstract) The method steps include 1) providing a layered structure having a photo-resist layer formed thereon; 2) patterning the photo-resist layer to form a photo-resist template mask and to expose a portion of the layered structure; 3) depositing a spacer-forming material layer above the photo-resist template mask and exposed portion of the layered structure; 4) etching the spacer-forming material layer to form a spacer mask; 5) removing photo-resist template mask; and, 6) transferring the image of the cropped spacer mask to the layered structure. (See FIG. 2). The content of U.S. Pat. No. 8,357,618 is hereby incorporated by reference into the present application.

“Multiple Patterning” as described in Wikipedia, the free encyclopedia, as of Mar. 25, 2013 describes a number of examples. The simplest case of multiple patterning is said to be double patterning, where a conventional lithography process is enhanced to produce double the expected number of features. The resolution of a photoresist pattern is said to begin to blur at around 45 nm half-pitch. For the semiconductor industry, therefore, double patterning was introduced at the 32 nm half-pitch node and below, mainly using state-of-the-art 193 nm immersion lithography tools.

The Wikipedia reference discusses Dual-Tone Photoresist; Dual-Tone Development; Self-aligned Spacer; Double/Multiple Exposure; Double Expose, Double Etch (mesas); Double Expose, Double Etch (trenches); Directed Self-Assembly; Multiple Patterning; and, 2D Layout Considerations. A number of implementations are discussed, along with industrial adoptions. The “Self-aligned Spacer” description is a spacer film layer formed on the sidewall of a pre-patterned feature. A spacer is formed by deposition or reaction of the film on the previous pattern, followed by etching to remove all the film material on the horizontal surfaces, leaving only the material on the sidewalls. By removing the original patterned feature, only the spacer is left. However, since there are two spacers for every line, the line density has now doubled. The spacer technique is said to be applicable for defining narrow gates at half the original lithographic pitch, for example. The spacer approach is said to be unique in that with one lithographic exposure, the pitch can be halved indefinitely with a succession of spacer formation and pattern transfer processes. The “indefinitely” has limitations of course, because the lithographic exposure tools have imaging size limitations. The spacer materials are said to commonly be hardmask materials, since their post-etch pattern quality tends to be superior compared to photoresist profiles after etch, which typically suffer from line edge roughness.

The main issues with the spacer approach are said to be whether the spacers can stay in place after the masking material over which they were applied is removed; whether the spacer profile is acceptable; and, whether the material underlying the spacer is attacked by the process used to remove the masking material which defined spacer deposition. The present invention directly addresses these problems which are mentioned in the Wikipedia article regarding multiple patterning. In addition to addressing these problems, the present invention enables designs which make use of more than one gate length. The invention describes a technique for fine tuning gate lengths down to 1 nm using sidewall spacer patterning.

### SUMMARY

The present invention embodiments relate to the formation of field effects transistors having multiple gate lengths on a single chip surface, where differences in gate lengths may be 1 nm or less.

The embodiments make use of hard masking materials to form spacers which subsequently act as hard masks during etching of transistor gates (or dummy gates). To provide multiple gate lengths, the width of a portion of the hard masking material spacers must be trimmed or increased.

When trimming is used to provide multiple gate lengths, an imaging mask is applied over the surface of the hard masking material which is to be trimmed, followed by imaging and patterning of the imaging mask over the hard masking material. Typical examples of imaging masking materials which may be used include, for example and not by way of limitation, the AX series and TX series resists available from AZ Electronic Materials; the Epic , UVN, and UV series resists available from DOW; the FEP-100, FEN-100, GAR, and PMMA series of resists available from Fujifilm; the ARX series, M series, V series and NDS series of resists available from JSR Micro; the PMGI and LOR series of resists available from MacDermid; and the PMMA series of resists available from Microchem. Typical patterning techniques which may be used in combination with the imaging masking materials listed above include DUV, EUV, EUVL, AMOL, EBDW, EBES, immersion optics, various laser exposure techniques, and combinations of these, by way of example and not by way of limitation.

Due to the size range of the trimming to be carried out (typically from about 1 nm to about 5 nm), the trimming or increase in width of a given hard masking material spacer, during a single operational step, may then be on the order of about 0.5 nm per side or greater, to reduce or increase an overall width of a spacer by 1.0 nm or greater. Control over the precise amount of width change per trimming step (which may be reiterated a number of times to achieve a desired result) determines the possibilities available. A trimming step may be carried out a number of times, to provide a highly controlled and self-limiting etch process.

Once the trimming is complete, the imaging mask material may be removed by an ashing process carried out under conditions which do not affect the hard masking material, by way of example and not by way of limitation.

When a gate width is increased by enlargement of a portion of a spacer, the enlargement is typically carried out by controlled deposition of an add-on hard masking material, to a given thickness, at a particular location on the spacer surface. The add-on hard masking material needs to adhere to the surface of the spacer hard masking material and not to the surface of a patterning masking material which overlies the original spacer hard masking material. In addition, the add-on hard masking material applied by the controlled deposition must not be affected by the ashing conditions used subsequently to remove the patterning masking material. An example of a technique used to create add-on hard masking material is ALD, by way of example and not by way of limitation.

Examples of patterning masking materials which are used in combination with an amorphous carbon hard mask layer, and which are capable of patterning at the 1 nm to 5 nm size range, are materials which do not include hydroxyl groups which may act as ALD nucleation sites at the time a hard masking material used to increase gate width is applied. This is so that upon ashing to remove the patterning masking material, there will not be patterning masking material underlying the ALD-deposited hard masking material, which might then be removed by the ashing, weakening the ALD-deposited hard masking material adhesion and potentially affecting the performance of the field affects transistor formed using the present inventive method.

Patterning masking materials which meet the requirements described directly above include a super-hydrophobic material formed from precursors selected from an organometallic compound, a metal chloride, a silane compound, and combinations thereof, for example and not by way of limitation. The metal chloride compound may be selected from the group consisting of aluminum trichloride, titanium tetrachloride, silicon tetrachloride and combinations thereof, by way of example and not by way of limitation. The silane compound may be selected from the group consisting of a chlorosilane, an amino silane, and combinations thereof, by way of example and not by way of limitation. Patterning masking materials may also be produced where a thin layer of an organometallic compound is first deposited, followed by deposition of a non-chlorinated alkylsilane which bonds to any surface hydroxyl groups present on an ALD seed layer of an organometallic material.

Other embodiments of super-hydrophobic materials which may be used as patterning masking include block copolymer thin films which are infiltrated with alumina or titania. Materials of this kind are generally known in the art, including block copolymer materials such as polystyrene-block-polydimethylsiloxane (PS-b-PDMS) or polystyrene-block poly(ferrocenylsilane) (PS-b-PFS). Sequential Infiltration Synthesis (SIS) of aluminum-based or titanium-based compounds into other block copolymers such as PS-b-PMMA is also known to lead to improved hydrophobicity.

In some instances, a second patterning masking material of the kind more generally known in the art may be applied over a first hydrophobic patterning masking material of the kind described directly above. After use of the second patterning masking material to pattern the first, hydrophobic patterning masking material, the second patterning masking material may be removed, preferably using ashing or a plasma etch technique which does not affect the first hydrophobic patterning mask. The patterned first hydrophobic mask is then used during application of the add-on hard masking material to gate structures, for purposes of increasing gate length at particular locations. Subsequently, the hydrophobic patterning mask is ashed, leaving the add-on hard masking material on place at the desired gate width location.

More general embodiments of the present invention are described in more detail with reference to the DRAWINGS and DETAILED DESCRIPTION which follow this SUMMARY.

### BRIEF DESCRIPTION OF THE DRAWINGS

The drawings which are presented herein have been modified from drawings present in U.S. Pat. No. 8,357,618 to Bencher et al., issued Jan. 22, 2013. FIGS. 2A-2G of the present drawings were taken from FIGS. 6A-6G of the '618 patent. However, the drawings are not labeled “Prior Art”, because the materials and processes used to form the structures illustrated are different. The present invention makes use of a new and improved concept to produce the structures shown in FIGS. 6A through 6G.

FIG. 1 is a Flowchart 100 representing a series of operations in a frequency doubling fabrication process, in accordance with one embodiment of the present invention.

FIGS. 2A-2G illustrate cross-sectional views representing a series of operations from Flowchart 100 of FIG. 1 as applied to a layered structure in accordance with one embodiment of the present invention.

### DETAILED DESCRIPTION OF EXEMPLARY EMBODIMENTS

As a preface to the detailed description, it should be noted that, as used in this specification and the appended claims, the singular forms “a”, “an”, and “the” include plural referents, unless the context clearly dictates otherwise.

When the word “about” is used herein, this is intended to mean that the nominal value presented is precise within ±10%.

The present invention embodiments relate to the formation of field effects transistors having multiple gate lengths on a single chip surface, where differences in gate lengths may be 1 nm or less.

The embodiments make use of varying materials and processes to form spacers which subsequently act as hard masks during etching of transistor gates (or dummy gates). To provide multiple gate lengths, the width of a portion of the hard masking material spacers must be trimmed or increased.

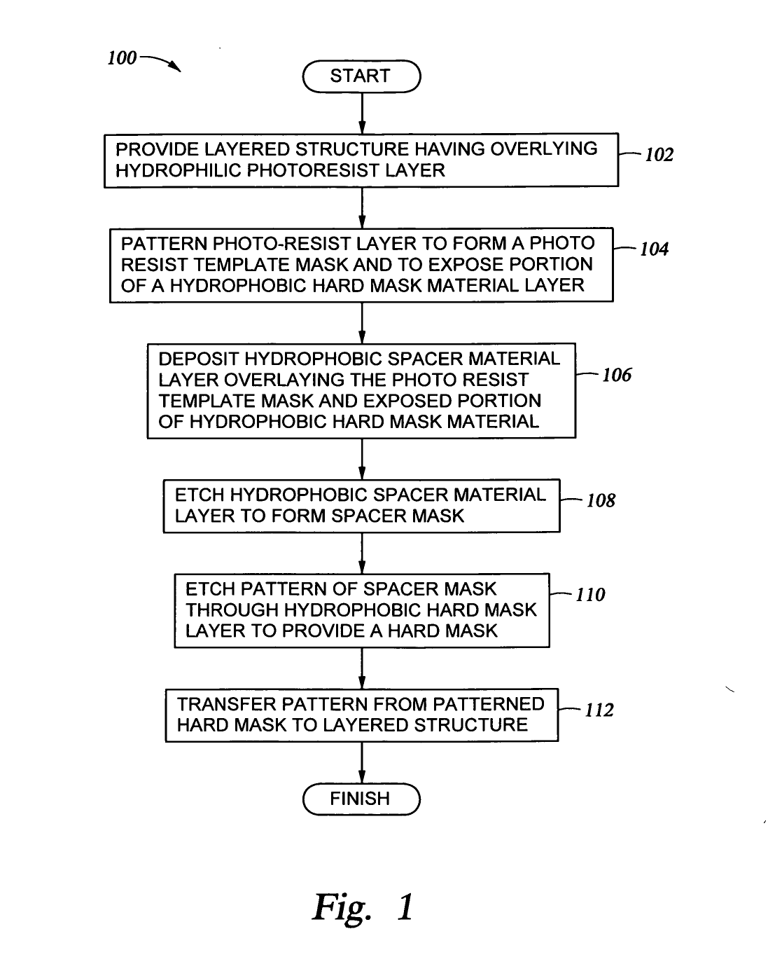

FIG. 1 shows a series of steps which may be used within a process to increase the number of features on the surface of a substrate over the number which can be produced using available lithographic imaging systems. The present invention particularly relates to the formation of field effects transistors having multiple gate lengths on a single chip surface, where differences in gate lengths may be 1 nm or less.

The embodiments make use of hard masking materials to form spacers which subsequently act as hard masks during etching of transistor gates (or dummy gates). To provide multiple gate lengths, the width of a portion of the hard masking material spacers must be trimmed or increased.

When trimming is used to provide multiple gate lengths, an imaging mask is applied over the surface of the hard masking material which is to be trimmed, followed by imaging and patterning of the imaging mask over the hard masking material. Typical examples of imaging masking materials which may be used are selected from the group consisting of the AX series and TX series resists available from AZ Electronic Materials; the Epic, UVN, and UV series resists available from DOW; the FEP-100, FEN-100, GAR, and PMMA series of resists available from Fujifilm; the ARX series, M series, V series and NDS series of resists available from JSR Micro; the PMGI and LOR series of resists available from MacDermid; and the PMMA series of resists available from Microchem, by way of example, and not by way of limitation. Typical patterning techniques which may be used in combination with the imaging masking materials listed above include DUV, EUV, EUVL, AMOL, EBDW, EBES, immersion optics, and various laser exposure techniques, and combinations of these, by way of example and not by way of limitation.

Due to the size range (typically from about 1 nm to about 5 nm) of the trimming to be carried out, the trimming or increase in width of a given hard masking material spacer, during a single operational step, may then be on the order of about 0.5 nm per side or greater, to reduce or increase an overall width of a spacer by 1.0 nm or greater. Control over the precise amount of width change per trimming step (which may be reiterated a number of times to achieve a desired result) determines the possibilities available. A trimming step may be carried out a number of times, to provide a highly controlled and self-limiting etch process.

Once the trimming is complete, the imaging mask material may be removed by an ashing process or a dry etch process carried out, by way of example and not by way of limitation, using materials and conditions which do not affect the hard masking material.

When a gate width is increased by enlargement of a portion of a spacer, the enlargement is typically carried out by controlled deposition of an add-on hard masking material, to a given thickness, at a particular location on the spacer surface. The add-on hard masking material needs to adhere to the surface of the spacer hard masking material and not to the surface of a patterning masking material which overlies the original spacer hard masking material. In addition, the add-on hard masking material applied by the controlled deposition must not be affected by the ashing conditions or the dry etch conditions used subsequently to remove the patterning masking material. An example of one technique used to create add-on hard masking material is ALD, by way of example and not by way of limitation.

Examples of pattern masking materials useful when an increase in gate width is required are materials which do not include hydroxyl groups which may act as ALD nucleation sites. In addition, the masking materials need to be capable of patterning at the 1 nm to 5 nm size range. The nucleation sites are important when ashing is used to remove the patterning masking material. If there is ALD-deposited hard masking material which continues past the desired deposition area and onto the edge of the patterning masking material, this ALD-deposited material will be removed by the ashing and may weaken the ALD-deposited hard masking material adhesion in the desired deposition area, potentially affecting the performance of the field affects transistor formed using the present inventive method.

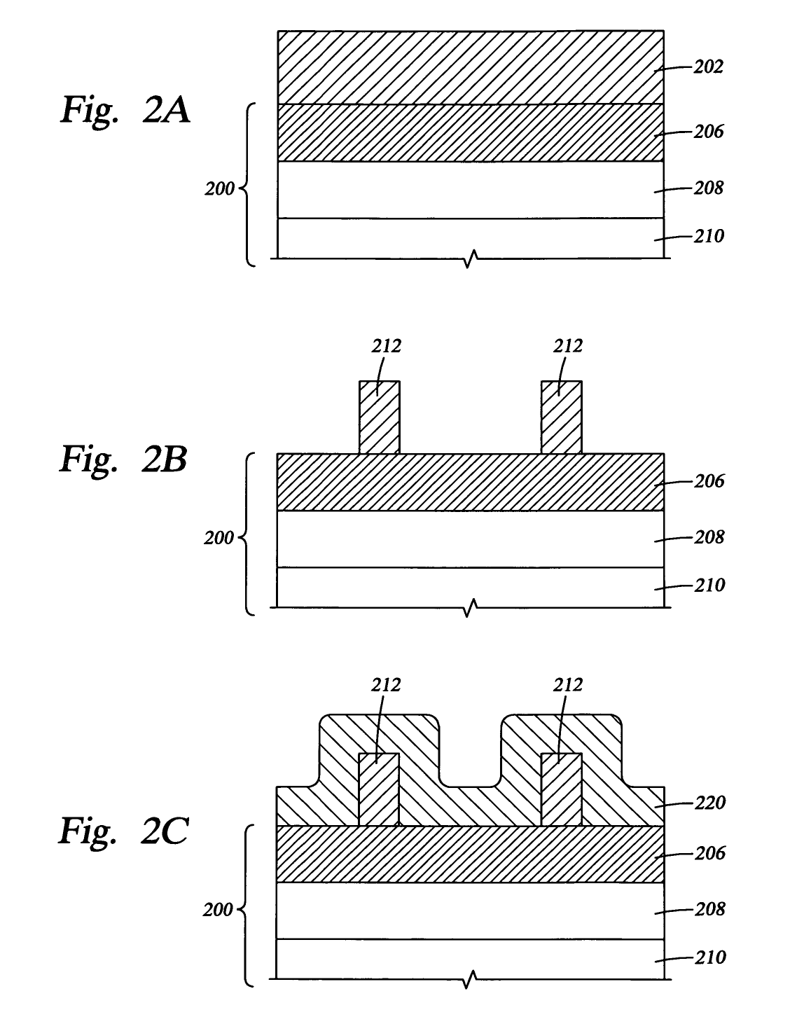

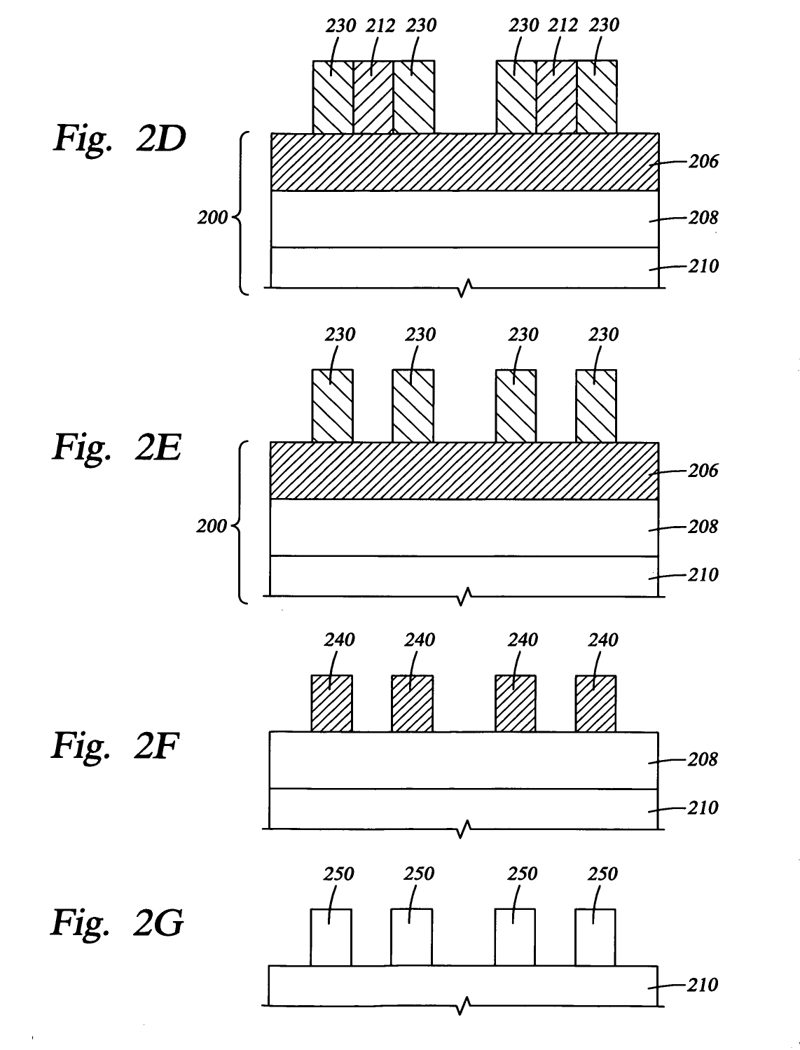

FIG. 1 illustrates a Flowchart 100 in accordance with an embodiment of the present invention where the hard masking material present on the device substrate is a hydrophobic material. Flowchart 100 is related to a method of doubling the number of features produced on a substrate surface when available lithographic imaging systems cannot meet the dimensional requirements. This method may be used to reduce the spacing between features such as transistor gate structures, for example and not by way of limitation. FIGS. 2A-2G illustrate cross-sectional views of an embodiment structure which can be produced using the steps in Flowchart 100.

Referring to operation 102 of Flowchart 100 and corresponding FIG. 2A, a structure 200 is provided having a photoresist layer 202 formed thereon. Structure 200 is comprised of an amorphous carbon hard-mask layer 206 which is hydrophobic in nature and which may have been treated to increase surface hydrophobicity, for example. A portion of the top surface of the strongly hydrophobic amorphous carbon hard mask layer 206 is exposed after patterning and development of photoresist layer 102 which comprises a hydrophilic material which is able to attach to the hydrophobic surface of amorphous carbon mask layer 206 well enough to stay in place during the formation of the structure shown in FIG. 2D.

Referring to operation 104 of Flowchart 100 and corresponding FIG. 2B, the photoresist layer 202 is patterned to form a photoresist template mask 212. A portion of upper surface of the amorphous carbon hard-mask layer 206 is exposed during the patterning of photoresist layer 202 to produce resist template mask 212.

Referring to operation 106 of Flowchart 100 and corresponding FIG. 2C, a spacer-forming material layer 220 is deposited above and conformal with photoresist template mask 212. Spacer forming material 220 is selected to be sufficiently hydrophobic that it bonds well to the surface of the amorphous carbon hard-mask layer 206, and bonds poorly to the exterior surfaces of photoresist template mask 212.

Referring to operation 108 of Flowchart 100 and corresponding FIG. 2D, spacer-forming layer 220 is etched to provide a spacer mask 230. The lines produced in spacer mask 230 provide 2 lines for spacer mask 230 for every line of photoresist template mask 212. The dry etchant used to remove template mask 212 is an etchant which easily contacts and reacts well with the hydrophilic material of template mask 212 and which is repelled by the hydrophobic surface of the amorphous carbon hard mask layer 206. As a result, the bonding between spacer mask 230 and amorphous carbon hard mask layer 206 remains strong.

Referencing operation 110 of Flowchart 100 and corresponding FIG. 2E, spacer mask 230 is used to etch amorphous hard mask layer 206, thereby producing hard mask 240. The upper surface of the device layer 208 is now exposed in areas not occupied by hard mask 240.

Referencing operation 112, the pattern of hard mask 240 is transferred into device layer 250.

Examples of patterning masking materials which may be used to form a strong hydrophobic layer over the surface of the amorphous carbon hard mask layer 206 include a super-hydrophobic material formed from precursors selected from an organometallic compound, a metal chloride, a silane compound, and combinations thereof, for example and not by way of limitation. The metal chloride compound may be selected from the group consisting of aluminum trichloride, titanium tetrachloride, silicon tetrachloride and combinations thereof, by way of example and not by way of limitation. The silane compound may be selected from the group consisting of a chlorosilane, an amino silane, and combinations thereof, by way of example and not by way of limitation. Patterning masking materials may also be produced where a thin layer of an organometallic compound is first deposited, followed by deposition of a non-chlorinated alkylsilane which bonds to any surface hydroxyl groups present on an ALD seed layer of an organometallic seed layer.

Other embodiments of super-hydrophobic materials which may be used as patterning masking include block copolymer thin films which are infiltrated with alumina or titania. Materials of this kind are generally known in the art, including block copolymer materials such as polystyrene-block-polydimethylsiloxane (PS-b-PDMS) or polystyrene-block poly(ferrocenylsilane) (PS-b-PFS). Sequential Infiltration Synthesis (SIS) of aluminum-based or titanium-based compounds into other block copolymers such as PS-b-PMMA is also known to lead to improved hydrophobicity.

In some instances, a second patterning masking material of the kind more generally known in the art may be applied over a first hydrophobic patterning masking material of the kind described directly above. After use of the second patterning masking material to pattern the first, hydrophobic patterning masking material, the second patterning masking material may be removed, preferably using ashing or a plasma etch technique which does not affect the first hydrophobic patterning mask. The patterned first hydrophobic mask is then used during application of the add-on hard masking material to gate structures, for purposes of increasing gate length at particular locations. Subsequently, the hydrophobic patterning mask is ashed, leaving the add-on hard masking material in place at the desired gate width location.

One of skill in the art will recognize that should the hard masking layer 206 comprise a hydrophilic material, the above description would be reversed in terms of composition. For example, the spacer-forming layer 220 would be selected to be sufficiently hydrophilic that it bonds well to the surface of the hard masking layer 206 and does not bond well to the photoresist layer 202 which is used to form template mask 212.

The above described exemplary embodiments are not intended to limit the scope of the present invention, as one skilled in the art can, in view of the present disclosure, expand such embodiments to correspond with the subject matter of the invention claimed below.

We claim:

1. A method of increasing the number of features on a semiconductor substrate comprising field effects transistors beyond the number which can be created directly using lithographic imaging tools, wherein said method comprises:
a) providing a semiconductor substrate surface having an overlying layer of a hydrophobic hard masking material;
b) depositing a layer of photoresist material over said hydrophobic hard masking material, wherein said photoresist material is generally hydrophilic in nature while capable of attaching to said hydrophobic hard mask material;
c) patterning said hydrophilic photoresist material to form a photoresist template mask and to expose a portion of said hydrophobic hard mask material layer which is present beneath said template mask on an upper surface of said semiconductor substrate;
d) depositing a hydrophobic spacer material layer overlying said photoresist template mask and exposed portion of hydrophobic hard mask material;
e) etching said spacer material layer to form a patterned spacer mask;
f) etching a pattern of said patterned spacer mask through said hydrophobic hard mask material layer to provide a hard mask; and
g) transferring said pattern from said patterned hydrophobic hard mask to an underlying layer present on an upper surface of said semiconductor substrate.

2. A method in accordance with claim 1, wherein said photoresist material which is generally hydrophilic in nature is capable of attaching to said hydrophobic hard mask material layer to a degree that said photoresist material remains in place through patterning of said photoresist template mask and through depositing of a hydrophobic spacer material layer, wherein dimensions of features present in said hydrophilic photoresist template are altered only to a degree such that the pattern transferred into said underlying layer of said semiconductor substrate surface remains useful for its intended purpose.

3. A method of increasing the number of features on a semiconductor substrate surface comprising field effects transistors beyond the number which can be created directly using lithographic imaging tools, wherein said method comprises:
a) providing a semiconductor substrate surface having an overlying layer of a hydrophilic hard masking material;
b) depositing a layer of photoresist material over said hydrophilic hard mask material, wherein said photoresist material is generally hydrophobic in nature, while capable of attaching to said hydrophilic hard masking material;
c) patterning said photoresist material to form a photoresist template mask and to expose a portion of said hydrophilic hard masking material layer which is present beneath said template mask on an upper surface of said semiconductor substrate;
d) depositing a hydrophilic spacer material layer overlying said photoresist template mask and exposed portion of hydrophilic hard masking material;
e) etching said spacer material to form a spacer mask;
f) etching a pattern of said spacer mask through said hydrophilic hard masking material layer to provide a hard mask; and
g) transferring said pattern from said patterned hydrophilic hard mask to an underlying layer present on an upper surface of said semiconductor substrate.

4. A method in accordance with claim 3, wherein said photoresist material which is hydrophobic in nature is capable of attaching to said hydrophilic hard masking material layer to a degree that said photoresist material remains in place during patterning of said photoresist template mask and during depositing of a hydrophilic spacer material layer, wherein dimensions of features in said hydrophobic photoresist template are altered only to a degree such that the pattern transferred into said underlying layer of said semiconductor substrate surface remains useful for its intended purpose.
